(19) United States
(12) Patent Application Publication
(10) Pub. No.: US 2004/0160749 A1
(43) Pub. Date: Aug. 19, 2004

(54) Mechanism for interconnecting two parallel circuit boards

(75) Inventors: Chin-Kai Sun, Pan-Chiao City (TW); Chia-Ming Hsieh, Nan-Chou Hsiang (TW)

Correspondence Address: Richard P. Berg, Esq., c/o LADAS & PARRY, Suite 2100, 5670 Wilshire Boulevard, Los Angeles, CA, 90036-5679, US

(73) Assignee: BENQ CORPORATION

(21) Appl. No.: 10/779,396

(22) Filed: Feb. 13, 2004

(30) Foreign Application Priority Data
Feb. 14, 2003 (TW) 092202413

(51) Int. Cl. H05K 5/00

(52) U.S. Cl. 361/759

(57) ABSTRACT

A mechanism for connecting a horizontal upper circuit board to a horizontal lower circuit board includes two insulating bodies fixed respectively on two opposite side portions of the lower circuit board, and two flexible retaining hooks fixed respectively on and projecting respectively and upwardly from the insulating bodies. Each of the insulating bodies has an inner side surface that is formed with a row of pin holes, each of which has a resilient conductive pin mounted therein. The upper circuit board is retained between the retaining hooks, and is clamped between abutment faces of the retaining hooks and upper contact portions of the conductive pins.

### CROSS-REFERENCE TO RELATED APPLICATION

This application claims priority of Taiwanese Application No-092202413, filed on Feb. 14, 2003.

### BACKGROUND OF THE INVENTION

1. Field of the Invention

This invention relates to a mechanism for interconnecting two circuit boards, and more particularly to a mechanism for interconnecting two parallel circuit boards

2. Description of the Related Art

Referring to FIGS. 1 and 1A, a conventional mechanism 91 interconnecting a vertical circuit board 92 and a horizontal circuit board 93 is shown to include an insulating body 911 that has two parallel rows of pin holes 912, and a plurality of conductive pins 913 secured respectively within the pin holes 912 in the insulating body 911. The insulating body 911 further has a slot 914 that extends along a longitudinal direction thereof. The vertical circuit board 92 has a lower side portion 921 that is inserted into the slot 914 in the insulating body 911, and two rows of electrical contacts 922 that are disposed respectively on two opposite side surfaces of the vertical circuit board 92. The conductive pins 913 have upper contact portions 915 that are respectively in electrical connection with the electrical contacts 922 of the vertical circuit board 92, and lower contact portions 916 that are welded to the horizontal circuit board 93 so as to establish electrical connection between the vertical circuit board 92 and the horizontal circuit board 93. However, high manufacturing precision is required for forming the slot 914 in the insulating body 911 so that the lower side portion 921 of the vertical circuit board 92 can be received fittingly therein. Furthermore, since the vertical circuit board 92 is configured as a cantilever, it tends to slant, thereby affecting adversely electrical signal transmission between the vertical circuit board 92 and the horizontal circuit board 93 and causing damage to the conductive pins 913.

### SUMMARY OF THE INVENTION

The object of this invention is to provide a mechanism for interconnecting two circuit boards firmly so as to establish effective electrical connection between the circuit boards.

According to this invention, a mechanism for connecting a horizontal upper circuit board to a horizontal lower circuit board includes two insulating bodies fixed respectively on two opposite side portions of the lower circuit board, and two flexible retaining hooks fixed respectively on and projecting respectively and upwardly from the insulating bodies. Each of the insulating bodies has an inner side surface that is formed with a row of pin holes, each of which has a resilient conductive pin mounted therein. The upper circuit board is retained between the retaining hooks, and is clamped between abutment faces of the retaining hooks and upper contact portions of the conductive pins

### BRIEF DESCRIPTION OF THE DRAWINGS

These and other features and advantages of this invention will become apparent in the following detailed description of the preferred embodiments of this invention, with reference to the accompanying drawings, in which:

FIG. 1 is a schematic, fragmentary side view of a conventional mechanism for interconnecting two circuit boards;

FIG. 1A is a perspective view of an insulating body of the conventional mechanism;

FIG. 2 is a partly exploded perspective view of the first preferred embodiment of a mechanism for interconnecting two parallel circuit boards according to this invention;

FIG. 3 is a partly sectional, partly exploded side view of the first preferred embodiment;

FIG. 4 is a fragmentary sectional view of the first preferred embodiment, taken along Line IV-IV in FIG. 2;

FIG. 5 is a schematic fragmentary side view of the first preferred embodiment, illustrating how a retaining hook of the first preferred embodiment is flexed when an upper circuit board is pressed downwardly on the retaining hook during assembly;

FIG. 6 is an assembled perspective view of the first preferred embodiment FIG. 7 is a partly sectional side view of the first preferred embodiment;

FIG. 8 is a partly exploded perspective view of the second preferred embodiment of a mechanism for interconnecting two parallel circuit boards according to this invention; and

FIG. 9 is an assembled perspective view of the second preferred embodiment.

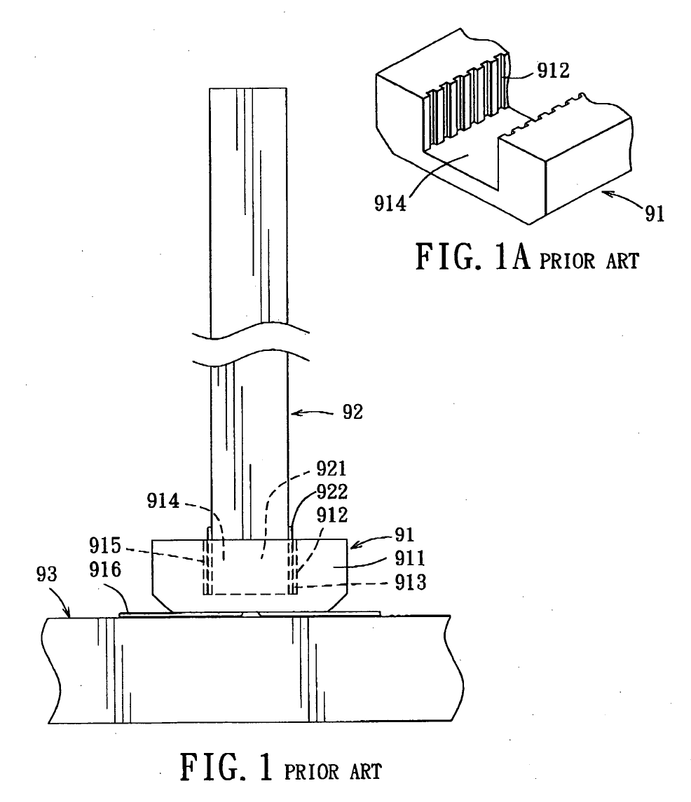

### DETAILED DESCRIPTION OF THE PREFERRED EMBODIMENTS

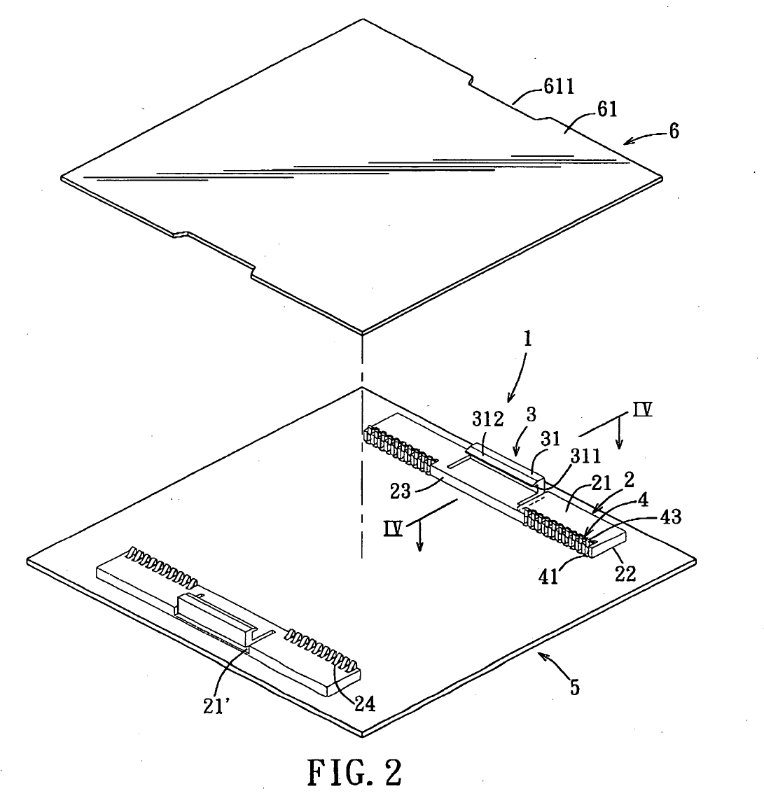

Referring to FIGS. 2, 3, 4, 5, 6, and 7, the first preferred embodiment of a mechanism 1 for interconnecting horizontal upper and lower circuit boards 6, 5 is shown to include two plastic insulating bodies 2, two retaining hooks 3, and a plurality of resilient conductive pins 4. The mechanism 1 and the upper and lower circuit boards 5, 6 constitute cooperatively a circuit board set. The lower circuit board 5 is rectangular. The upper circuit board 6 is rectangular, and has two opposite sides 61, each of which is formed with a notch 611 at a middle portion thereof. A bottom surface of the upper circuit board 6 is formed with a plurality of electrical contacts 612.

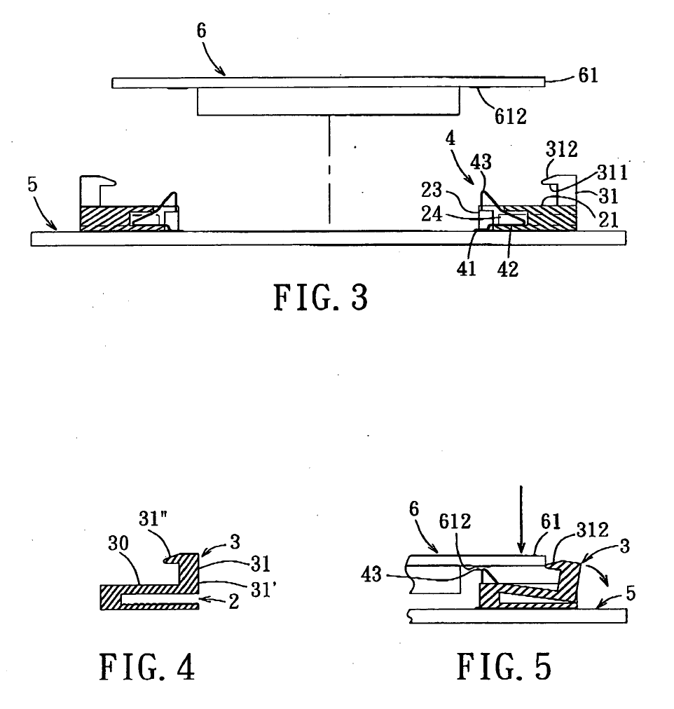

The insulating bodies 2 are elongated, and are fixed respectively on two opposite side portions of a top surface of the lower circuit board 5. Each of the insulating bodies 2 has a top surface 21 that is formed with a groove 21′ at a middle portion thereof, a bottom surface 22 that is attached fixedly to the lower circuit board 5, and an inner side surface 23 that is formed with a row of pin holes 24 (see FIGS. 2 and 3).

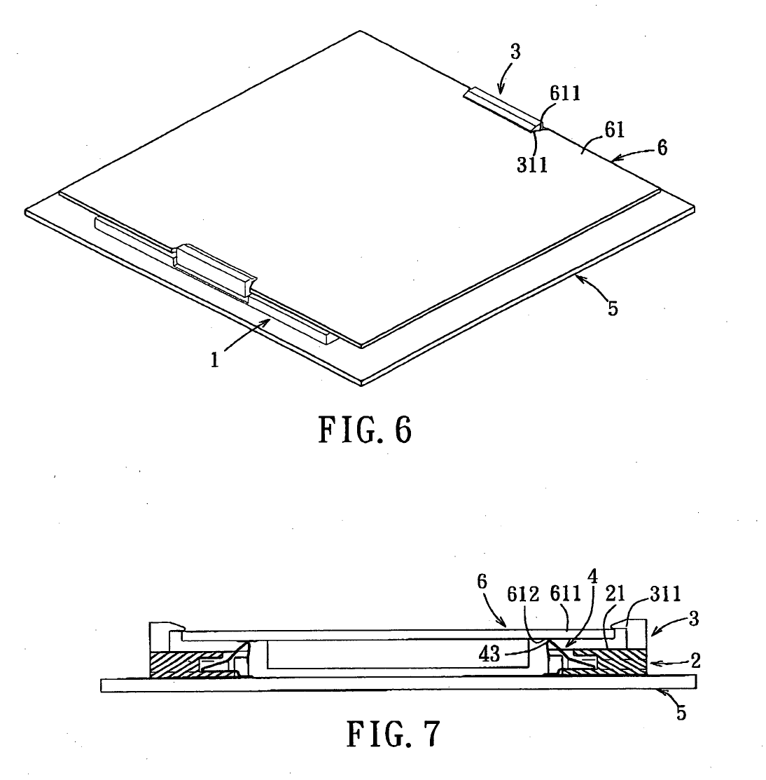

The retaining hooks 3 are fixed respectively within the grooves 21′ in the insulating bodies 2, and project respectively and upwardly from the insulating bodies 2. In each of the insulating bodies 2, two half rows of the pin holes 4 are located respectively at two opposite sides of the corresponding retaining hook 3. Each of the retaining hooks 3 includes a horizontal cantilever plate portion 30, and an inverted L-shaped hook portion 31. Each of the cantilever plate portions 30 has an inner end that is formed integrally with the corresponding insulating body 2, and an outer end that is formed integrally with a lower end of the corresponding hook portion 31. Each of the hook portions 31 has an upright plate portion 31′ (see FIG. 4) and a retaining portion 31″ (see FIG. 4) that extends laterally from an upper end of the upright plate portion 31′ and that is formed with an abutment face 311 (see FIG. 3) and a downwardly and inwardly inclined guiding face 312 (see FIG. 3). The upright plate portions 31′ extend respectively through the notches 611 in the upper circuit board 6. The retaining portions 31″ extend respectively from the upright plate portions 31′ toward each other so as to confine the upper circuit board 6 between the upright plate portions 31′ and between the abutment faces 311 and the top surfaces 21 of the insulating bodies 2, as shown in FIGS. 6 and 7. Alternatively, the retaining hooks 3 are made of metal, and are fixed on the insulating bodies 2, respectively.

The conductive pins 4 are disposed respectively within the pin holes 24 in the insulating bodies 2. Each of the conductive pins 4 has a lower contact portion 41 (see FIGS. 2 and 3) welded to the lower circuit board 5 such that the conductive pins 4 are in electrical connection with the lower circuit board 5, a V-shaped intermediate pin portion 42 (see FIG. 3) having a lower end formed integrally with the lower contact portion 41 and inserted into the corresponding pin hole 24, and an inverted V-shaped upper contact portion 43 formed integrally with the intermediate pin portion 42 and projecting upwardly from the top surface 21 of the corresponding insulating body 2. The upper contact portions 43 of the conductive pins 4 are biased to press respectively against the electrical contacts 612 of the upper circuit board 6 so as to connect the conductive pins 4 respectively and electrically with the electrical contacts 612 of the upper circuit board 6. As such, a top surface of the upper circuit board 6 is pressed against the abutment faces 311 of the retaining hooks 3 so as to clamp the upper circuit board 6 between the abutment faces 311 of the retaining hooks 3 and the upper contact portions 43 of the conductive pins 4.

Because the cantilever plate portions 30 of the retaining hooks 3 extend respectively from the insulating bodies 2 away from each other, the hook portions 31 of the retaining hooks 3 can move away from each other. As such, during assembly, when two opposite sides of the upper circuit board 6 are placed respectively on the inclined guiding faces 312 of the hook portions 31 of the retaining hooks 3 and when the upper circuit board 6 is pressed downwardly relative to the lower circuit board 5, the hook portions 31 of the retaining hooks 3 are pushed by the upper circuit board 6 to move away from each other, as shown in FIG. 5. As such, the upper circuit board 6 can move into a space between the retaining portions 31″ of the hook portions 31 of the retaining hooks 3 and the upper contact portions 43 of the conductive pins 4.

When it is desired to remove the upper circuit board 6 from the retaining hooks 3, it is only necessary to move the upper circuit board 6 forcibly and upwardly relative to the lower circuit board 5 so that the upper circuit board 6 pushes the hook portions 31 of the retaining hooks 3 away from each other.

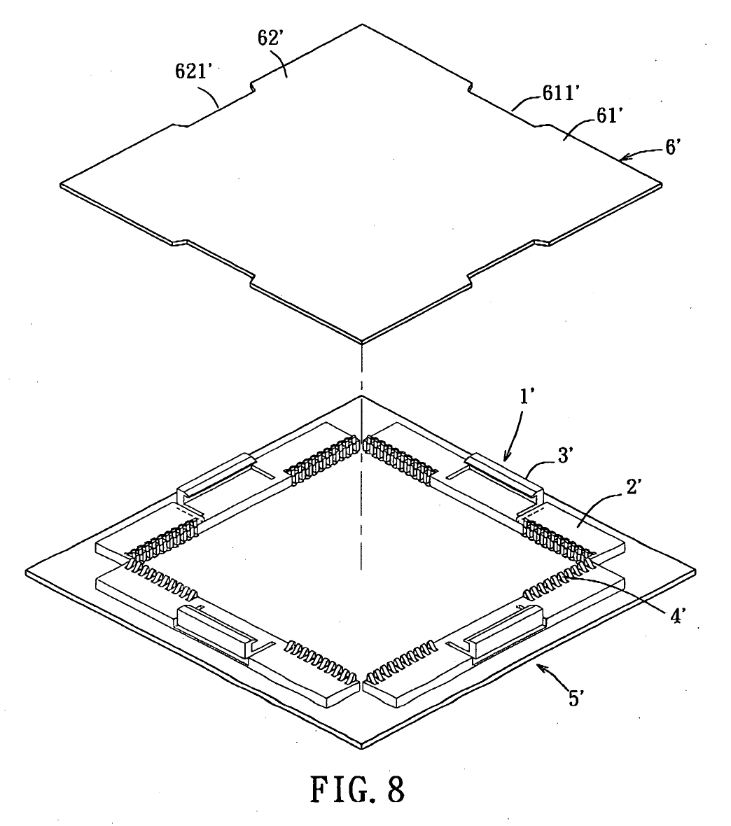

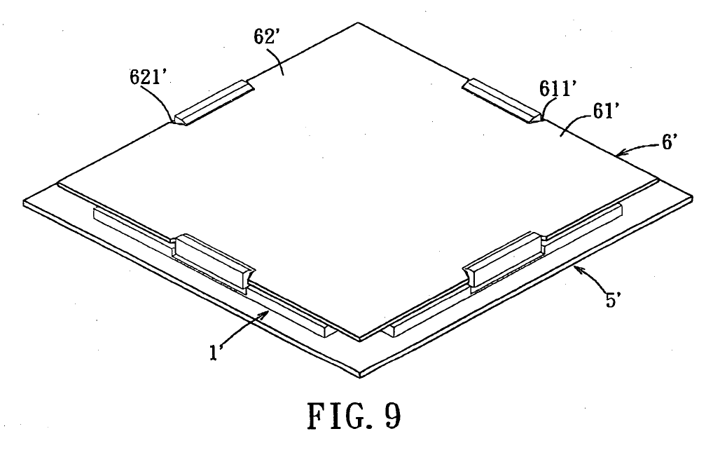

FIGS. 8 and 9 show the second preferred embodiment of a mechanism 1′ for interconnecting upper and lower circuit boards 5′, 6′ according to this invention. Unlike the first preferred embodiment, the upper circuit board 6′ has two opposite first sides 61′ and two opposite second sides 62′. Each of the first and second sides 61′, 62′ is formed with a notch 611′, 621′ at a middle portion thereof. The mechanism 1′ includes four insulating bodies 2′ disposed respectively on four sides of the lower circuit board 5′, four retaining hooks 3′ formed respectively with the insulating bodies 2′, and four rows of conductive pins 4′ disposed respectively on the insulating bodies 2′.

With this invention thus explained, it is apparent that numerous modifications and variations can be made without departing from the scope and spirit of this invention. It is therefore intended that this invention be limited only as indicated by the appended claims.

We claim:

1. A mechanism for connecting a horizontal upper circuit board to a horizontal lower circuit board, the upper circuit board having a bottom surface that is formed with a plurality of electrical contacts, said mechanism comprising:
an insulating body adapted to be fixed on a top surface of the lower circuit board, said insulating body having a top surface and an inner side surface that is formed with a row of pin holes;
a flexible retaining hook fixed on and projecting upwardly from said insulating body, said retaining hook including an inverted L-shaped hook portion that has an upright plate portion and a retaining portion which extends laterally from an upper end of said upright plate portion and which is formed with an abutment face so as to confine the upper circuit board between said abutment face and said top surface of said insulating body; and
a plurality of conductive pins disposed respectively within said pin holes, said conductive pins being in electrical connection with the lower circuit board.

2. The mechanism as claimed in claim 1, wherein said retaining hook is formed integrally with said insulating body.

3. The mechanism as claimed in claim 1, wherein said retaining hook further includes a horizontal cantilever plate portion that has an inner end which is connected fixedly to said insulating body.

4. The mechanism as claimed in claim 1, wherein said retaining hook has an inwardly and downwardly inclined guiding face so that one side of the upper circuit board can be placed on said inclined guiding face during assembly.

5. A circuit board set comprising:
an upper circuit board having a bottom surface that is formed with a plurality of electrical contacts;
a lower circuit board; and
a mechanism for connecting said upper circuit board to said lower circuit board, said mechanism comprising:
an insulating body fixed on a top surface of said lower circuit board, said insulating body having a top surface and an inner side surface that is formed with a row of pin holes,
a retaining hook fixed on and projecting upwardly from said insulating body, said retaining hook including an inverted L-shaped hook portion that has an upright plate portion and a retaining portion which extends laterally from an upper end of said upright plate portion and which is formed with an abutment face so as to confine said upper circuit board between said abutment face and said top surface of said insulating body, and
a plurality of conductive pins disposed respectively within said pin holes and in electrical connection with said lower circuit board and said upper circuit board, said upper circuit board being clamped between said abutment face of said hook portion of said retaining hook and said conductive pins.

6. The circuit board set as claimed in claim 5, wherein said retaining hook is formed integrally with said insulating body.

7. The circuit board as claimed in claim 5, wherein said retaining hook further includes a horizontal cantilever plate portion that has an inner end which is connected fixedly to said insulating body.
